(19) United States
(12) Patent Application Publication
(10) Pub. No.: US 2025/0372538 A1
(43) Pub. Date: Dec. 4, 2025

(54) METHOD OF MANUFACTURING SEMICONDUCTOR DEVICES AND CORRESPONDING SEMICONDUCTOR DEVICE

(71) Applicant: STMicroelectronics International N.V., Geneva (CH)

(72) Inventors: Marco ROVITTO, Milano (IT); Samuele ZALAFFI, Salsomaggiore (IT)

(73) Assignee: STMicroelectronics International N.V., Geneva (CH)

(21) Appl. No.: 19/215,057

(22) Filed: May 21, 2025

(30) Foreign Application Priority Data
May 30, 2024 (IT) 102024000012424

(51) Int. Cl. H01L 23/00; B22F 10/28; B29C 64/141; B29K 63/00; B29L 31/34; B33Y 10/00; B33Y 80/00; H01L 21/48; H01L 23/31

(52) U.S. Cl. CPC H01L 23/562; B22F 10/28; B33Y 10/00; B33Y 80/00; H01L 21/4821; H01L 23/3107; B22F 2998/10; B29C 64/141; B29K 2063/00; B29L 2031/3406

(57) ABSTRACT

A semiconductor die is arranged at a first region of a surface of a substrate. Add-on material is dispensed onto a second region of the surface of the substrate to provide a sculptured pattern of raised formations. An electrically insulating material is molded onto the surface of the substrate having the semiconductor die arranged at the first region of the surface of the substrate. The electrically insulating material encapsulates the semiconductor die as well as the sculptured pattern of raised formations provided at the surface of the substrate. The sculptured pattern of raised formations counters delamination of the electrically insulating material molded onto the surface of the substrate from the surface of the substrate.

### PRIORITY CLAIM

This application claims the priority benefit of Italian Application for Patent No. 102024000012424 filed on May 30, 2024, the content of which is hereby incorporated by reference in its entirety to the maximum extent allowable by law.

### TECHNICAL FIELD

The description relates to semiconductor devices.

One or more embodiments can be applied to semiconductor devices including integrated circuits (ICs), for instance.

### BACKGROUND

Current manufacturing processes of (integrated circuit-IC) semiconductor devices may comprise attaching a semiconductor die on a substrate (a leadframe, for instance) and, subsequently, providing an electrically insulating package to the device.

The package is provided by molding an electrically insulating molding compound (an epoxy resin, for instance) onto the substrate having the semiconductor die attached thereon.

Inadequate adhesion between the molding compound and the substrate (of metallic material in the case of a leadframe) may result in delamination of the package from the substrate.

In certain cases, the degree of delamination is such that humidity and contaminants can penetrate the package and reach the semiconductor die (or dice) therein, possibly causing reliability issues (die corrosion or detachment, for instance).

U.S. Pat. Nos. 7,821,113 B2, 6,329,706 B1, and United States Patent Application Publication Nos. 2020/0127637 A1, 2020/0020614 A1, 2020/0211982 A1, 2021/0217686 A1, 2019/0182997 A1 and 2018/0012848 A1 (all incorporated herein by reference) provide background information in the related technological area.

There is a need in the art to overcome the drawbacks discussed in the foregoing.

### SUMMARY

One or more embodiments relate to a method.

One or more embodiments relate to a corresponding (integrated circuit) semiconductor device.

In solutions as described herein, raised formations are formed at a surface of a substrate for semiconductor devices in order to counter undesired delamination of an electrically insulating encapsulation from the surface of the substrate.

Solutions as described herein may involve forming raised formations via additive manufacturing techniques, such as laser induced forward transfer (LIFT), for instance.

In solutions as described herein, raised formations may be formed prior and/or subsequently to arranging a semiconductor die at a die mounting region of the substrate.

In solutions as described herein, raised formations may be formed prior and/or subsequently to providing electrically conductive formations for a semiconductor die arranged at a die mounting region of the substrate.

Solutions as described herein may be applied to semiconductor devices having a leadframe as a substrate, where raised formations may be provided at a die pad and/or at leads in the leadframe.

### BRIEF DESCRIPTION OF THE DRAWINGS

One or more embodiments will now be described, by way of example only, with reference to the annexed figures, wherein:

FIG. 1 is a cross-sectional view of a semiconductor device illustrative of possible issues in conventional semiconductor devices,

FIGS. 2A to 2E are cross-sectional views illustrative of a sequence of processing steps according to embodiments of the present description, and

FIGS. 3 and 4 are cross-sectional views illustrative of semiconductor devices according to embodiments of the present description, and

FIGS. 5A to 5C are flow charts illustrative of sequences of processing steps according to various embodiments of the present description.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The headings/references used herein are provided merely for convenience and hence do not define the extent of protection or the scope of the embodiments.

For simplicity and ease of explanation, throughout this description, and unless the context indicates otherwise, like parts or elements are indicated in the various figures with like reference signs, and a corresponding description will not be repeated for each and every figure.

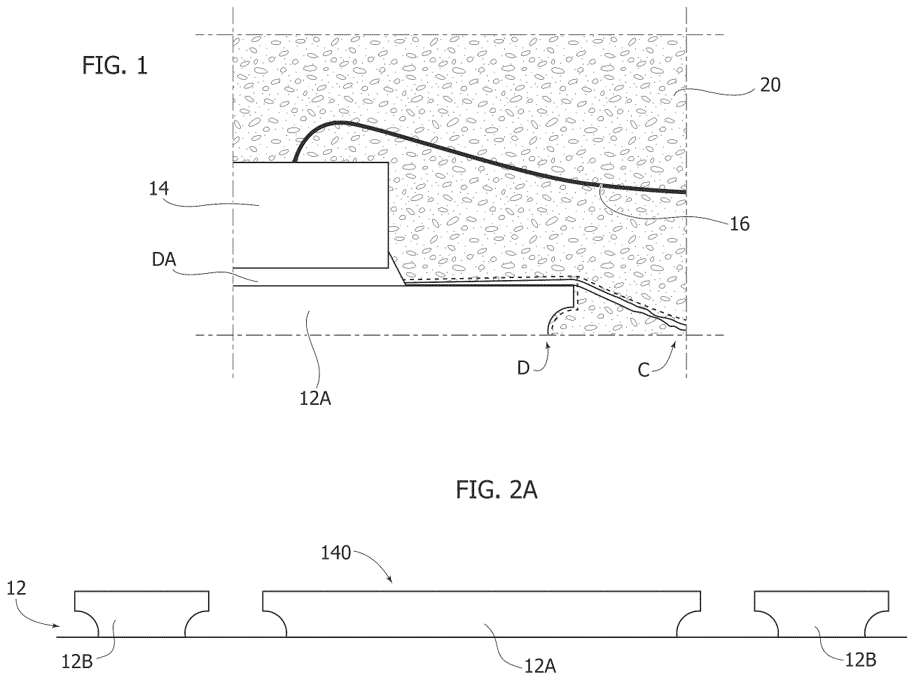

FIG. 1 is a cross-sectional view illustrative of a portion of an (integrated circuit-IC) semiconductor device 10 provided with a quad flat package (QFP).

A device 10 as illustrated in FIG. 1 comprises: a semiconductor die/chip 14 (the terms chip/s and die/dice are herein regarded as synonymous) attached at the top/front surface of a die pad 12A of a substrate such as a leadframe; and an electrically insulating package 20 encapsulating the leadframe having the semiconductor die 14 attached thereon.

The designation “leadframe” (or “lead frame”) is currently used (see, for instance the USPC Consolidated Glossary of the United States Patent and Trademark Office) to indicate a metal frame that provides support for an integrated circuit chip or die as well as electrical leads to interconnect the integrated circuit in the die or chip to other electrical components or contacts.

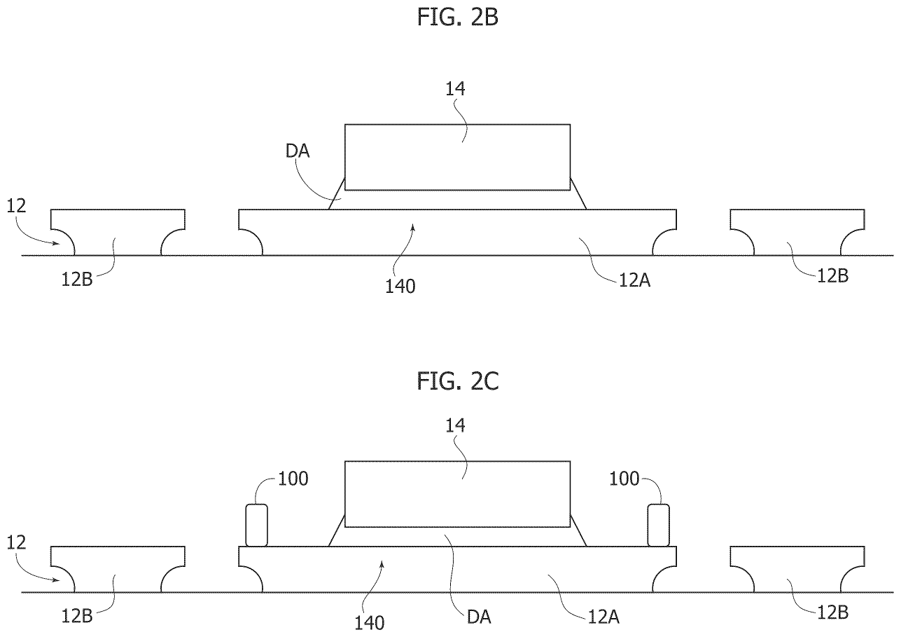

Essentially, a leadframe comprises an array of electrically-conductive formations or leads (visible in FIGS. 2A, for instance, and referred therein with the reference 12B) that from an outline location extend inwardly in the direction of a semiconductor chip or die 14 thus forming an array of electrically-conductive formations from a die pad 12A configured to have at least one (integrated circuit-IC) semiconductor die attached thereon. This may be via conventional means such as a die attach adhesive (a die attach film DA, for instance, as illustrated in FIG. 1).

As illustrated herein by way of example, an (integrated circuit) semiconductor device may also comprise electrically conductive formations 16 (wires, for instance) that couple the semiconductor die 14 to the leads (providing input/output signals, for instance) and/or to the die pad 12A (providing a ground level, for instance).

Manufacturing processes for obtaining a semiconductor device as illustrated in FIG. 1 are conventional in the art which makes it unnecessary to provide a more detailed discussion herein.

The electrically insulating package 20 may be provided by molding an electrically insulating molding compound (an epoxy resin, for instance) onto the leadframe having the semiconductor die 14 attached thereon (at the top/front surface of the die pad 12A).

In a semiconductor as exemplified in FIG. 1, possible reliability issues may arise from delamination of the package 20 from the leadframe and/or cracks in package 20.

Cracks in the molding compound 20 or delamination of the molding compound 20 from the surface of the die pad 12A or the leads 12B may cause humidity or contaminants to enter the package 20 and possibly to reach the die 14 arranged at the die pad 12A and causing failure of the device.

Delamination and/or cracks may start at the bottom surface of the device (at points D and C illustrated in FIG. 1, for instance) and progress along a delamination path (two possible delamination/cracking paths are illustrated in dashed lines in FIG. 1) into the package 20.

According to a conventional approach, delamination of the electrically insulating encapsulation 20 from the surface of the leadframe may be countered by forming a layer of adhesion promoter material at the surface of the leadframe. By way of example, so called non-etching adhesion promoters (NEAP) may be provided at the surface to enhance adhesion of the electrically insulating encapsulation to the leadframe.

However, NEAP processing may involve time- and/or cost-consuming processing steps. Moreover, it has been observed that a NEAP layer formed at the surface of a leadframe may (at least) partially dissolve when exposed to acidic baths, such as plating or de-flashing bath, commonly involved in the manufacturing processes of semiconductor devices.

According to other approaches, the surface of the leadframe may be or formed with grooves/notches in order to improve the adhesion with an encapsulation molded thereon. Such solutions might not be suitable in devices comprising relatively small die pads, for instance, where little room is available to provide such grooves (via punching/stamping, for instance).

U.S. Pat. No. 6,329,706 B1 (cited above) discloses a die pad formed with a raised rim in order to increase the delamination path from an outer surface of the device to a semiconductor die arranged at the die pad. Such raised rim is formed by bending a portion of the die pad. Such solutions may not be adequate in cases where the die pad is relatively small and/or thick, thus making forming such raised rim (via bending) to be difficult or complex.

In solutions as described herein, raised formations or formations are formed at a surface of a substrate for semiconductor devices in order to counter undesired delamination of an electrically insulating encapsulation from the surface of the substrate.

Solutions as described herein may involve forming raised formations via additive manufacturing techniques, such as laser induced forward transfer (LIFT), for instance.

In solutions as described herein raised formations may be formed prior and/or subsequently to arranging a semiconductor die at a die mounting region of the substrate.

In solutions as described herein raised formations may be formed prior and/or subsequently to providing electrically conductive formations for a semiconductor die arranged at a die mounting region of the substrate.

Solutions as described herein may be applied to leadframe based semiconductor devices, where raised formations may be provided at the die pad or at the leads.

FIGS. 2A to 2E are cross-sectional views illustrative of a sequence of processing steps according to embodiments of the present description.

It will be otherwise appreciated that the sequence of steps of FIGS. 2A to 2E is merely exemplary insofar as: one or more steps illustrated in FIGS. 2A to 2E can be omitted, performed in a different manner (with other tools, for instance) and/or replaced by other steps; additional steps may be added; and one or more steps can be carried out in a sequence different from the sequence illustrated.

In current manufacturing processes of semiconductor devices, plural devices are manufactured concurrently to be separated into single individual device in a final singulation. For simplicity and ease of explanation, the following description and related figures will refer to manufacturing a single device.

FIG. 2A is illustrative of a substrate 12 for semiconductor devices provided on a temporary (and possibly sacrificial) carrier. In various embodiments the substrate 12 may be a leadframe as illustrated in FIG. 2A, comprising a die pad 12A and an array of electrically conductive leads 12B arranged peripherally or sidewise of the die pad 12A.

The substrate 12 is configured to have a (integrated circuit-IC) semiconductor die arranged at a die mounting region 140 of the top/front surface. In embodiments where the substrate is a leadframe 12 the die mounting region 140 is located at the top/front surface of the die pad 12A.

In the following description, for ease of explanation, reference will be made to manufacturing processes of a device comprising a leadframe 12 as substrate; this is merely by way of example insofar as solutions as described herein may advantageously be applied to devices comprising substrates other than a leadframe as illustrated herein.

FIG. 2B is illustrative of a semiconductor die 14 arranged via die-attach material (a die attach film, for instance) at the die mounting region 140 of the top/front surface of a die pad 12A in a leadframe 12.

FIG. 2C is illustrative of a processing step where raised formations or structures 100 are formed at the top/front surface of the leadframe 12. According to embodiments of the present description, the raised formations (or structures) 100 may be formed via additive manufacturing techniques such as 3D printing or jetting, for instance.

Advantageously, a laser induced forward transfer (LIFT) technique may be used to form the raised formations 100 at the top/front surface of the leadframe 12.

Essentially, LIFT processing comprises a deposition process where material from a donor tape or sheet is transferred to an acceptor substrate (here the top/front surface of the leadframe 12) facilitated by laser pulses.

General information on the LIFT process can be found, for instance, in P. Serra, et al.: “Laser-Induced Forward Transfer: Fundamentals and Applications”, in Advanced Materials Technologies/Volume 4, Issue 1 (incorporated herein by reference).

Forming the raised formations 100 via LIFT may be advantageous in so far as LIFT facilitates a fine control over dispensing mode and geometry that can be varied, for instance, in order to increase adhesion of the raised formations 100 to the surface of the leadframe 12.

Whatever the particular technique, raised formations 100 may be formed by dispensing add-on material at the top/front surface of the substrate 12.

Both electrically conductive and electrically insulating add-on material may be used to form the raised formations 100.

Among the electrically conductive materials suitable choices comprise silver material, copper material and/or solder material (solder paste), for instance.

An (electrically insulating) adhesive epoxy may also be used to form the raised formations 100.

In various embodiments, raised formations 100 may be formed at the top/front surface of the die pad 12A, peripherally of the die mounting region 140, as illustrated in FIG. 2C.

The sculptured pattern of raised formations 100 may comprise raised formations formed as: pillar-like raised formations 100 peripherally of the die mounting region 140, or dike-like raised formations 100 around the die mounting region 140.

It is noted that raised formations as described in the foregoing (where raised formations 100 are formed at the surface of the substrate 12 having arranged a semiconductor die 14 at the die mounting region 140 thereof) can be formed at the top/front surface of the substrate 12 also prior to arranging a semiconductor die 14 at the die mounting region 140 of the substrate 12.

Said otherwise, in various embodiments the processing steps described in relation to FIGS. 2B and 2C can be performed in reverse order, thus involving arranging a semiconductor die 14 at the die mounting region 140 of a substrate (already) having raised formations 100 provided at the (front/top) surface thereof.

FIG. 2D is illustrative of a processing step where electrically conductive formations 16 (electrically conductive wires, for instance) are provided to electrically couple the semiconductor die 14 to selected leads 12B in the array of leads 12B.

As illustrated, the electrically conductive formations 16 have: a first terminal portion at die bonding pads provided at the top/front surface of the semiconductor die 14 (not visible in the figures for scale reasons), and a second terminal portion at a bonding region 160 at the leads 12.

As illustrated, solder material may be provided at the bonding region 160 at the leads 12B, to facilitate bonding of a terminal portion of the wires.

According to embodiments of the present description, raised formations 100 may be formed at the front/top surface of the substrate subsequently to providing electrically conductive formations to electrically couple the semiconductor die 14 to the leads 12B.

FIG. 2E is illustrative of an electrically insulating encapsulation 20 provided to the device by molding an electrically insulating molding compound (an epoxy resin, for instance) onto the assembly illustrated in FIG. 2D.

As discussed previously, delamination (or cracks) is more likely to start at points D1 of the interface between the substrate 12 and the electrically insulating encapsulation 20 that are exposed at the bottom/back surface of the device. A possible delamination path along the interface between the substrate 12 and the encapsulation 20 is illustrated with a dashed line in FIG. 2E.

It has been observed that raised formations 100 as illustrated in FIG. 2E counter propagation of delamination, that is, delamination does not go beyond a point D2 where it reaches the base of the raised formation 100 provided at the top/front surface of the substrate 12.

Moreover, in a worst-case scenario where delamination propagates beyond that point D2, it may be appreciated that the raised formation 100 increases the length of the delamination path to the semiconductor die 14 arranged at the top/front surface of the substrate 12.

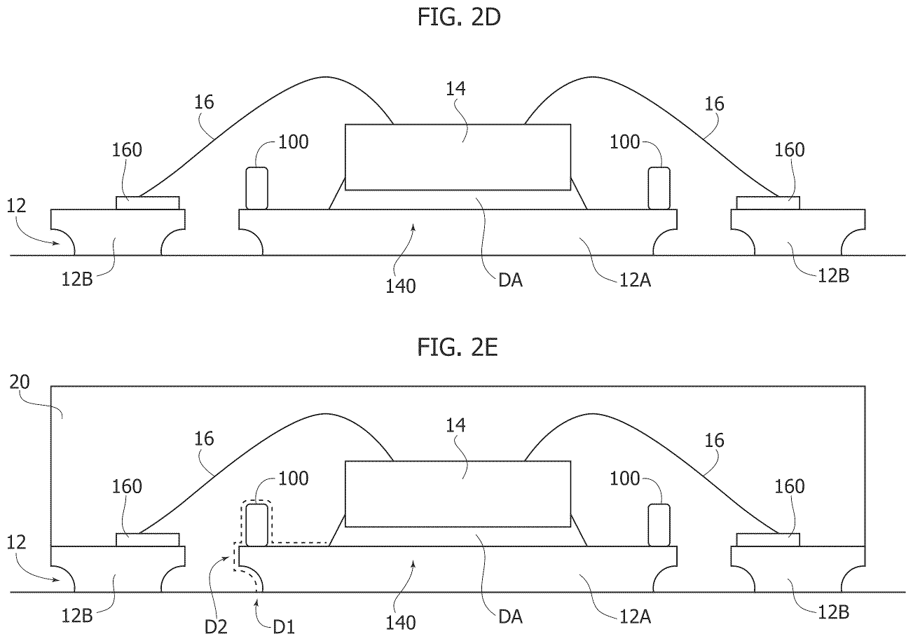

In various embodiments the raised formations 100 may be formed at the top/front surface of a leadframe 12 in locations others than the die pad 12A. For instance, as illustrated in FIG. 3, raised formations 100 may be formed at the top/front surface of selected leads 12B in the array of leads 12B.

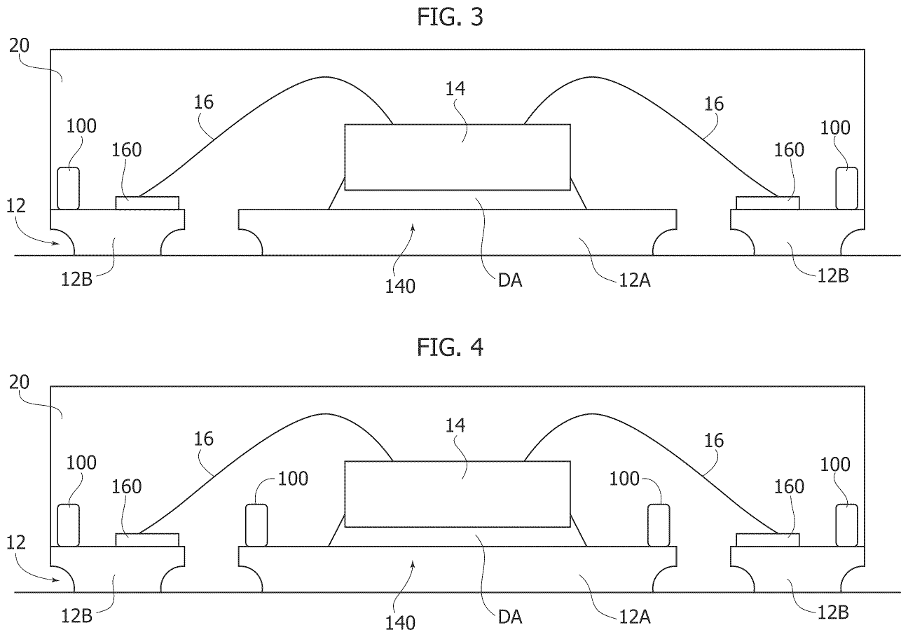

As illustrated in FIG. 4, raised formations 100 may be formed both at the top/front surface of the die pad 12A and at the top/front surface of selected leads 12B in the array of leads 12B.

Processing steps to obtain a semiconductor device having raised formations 100 as illustrated in FIG. 3 or FIG. 4 are similar to the processing steps described with reference to FIGS. 2A to 2E, and a similar description will not be repeated.

In summary, solutions according to embodiments of the present description involve: arranging a semiconductor die 14 at a first region 140 (a die mounting region, for instance) of a surface of a substrate 12, and dispensing add-on material onto a second region of the surface of the substrate 12.

The add-on material dispensed onto the surface of the substrate 12 provides a sculptured pattern of raised formations 100.

An electrically insulating material 20 is molded onto the surface of the substrate 12 having the semiconductor die 14 arranged at the first region 140 of the surface of the substrate 12. The electrically insulating material 20 encapsulates the semiconductor die 14 as well as the sculptured pattern of raised formations 100 provided at the surface of the substrate 12.

The sculptured pattern of raised formations 100 counters delamination of the electrically insulating material 20 molded onto the surface of the substrate 12 from the surface of the substrate 12.

The substrate 12 may be a leadframe comprising a die pad 12A including the first region 140 of the surface of a substrate 12 and an array of electrically conductive leads 12B arranged around the die pad 12A. Dispensing the add-on material onto the second region 140 of the surface of the substrate 12 comprises dispensing add-on material at at least one of the die pad 12A (as illustrated in FIG. 2E) and the array of electrically conductive leads 12B (as illustrated in FIG. 3).

Add-on material may be dispensed both at the die pad 12A and at the array of electrically conductive leads 12B (as illustrated in FIG. 4).

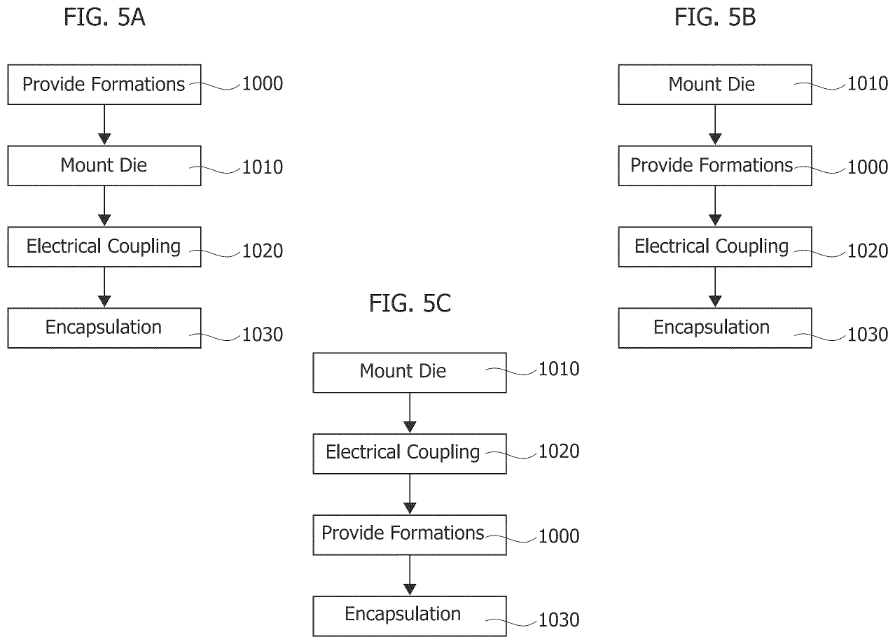

As mentioned previously, the order of processing steps described in relation to FIGS. 2A to 2E may be different than what is illustrated in the same sequence of Figures. FIGS. 5A to 5C are flow charts summarizing possible sequence of processing steps according to embodiments of the present description.

With reference to FIG. 5A processing as described herein may comprise:
1000—forming raised formations 100 at the top/front surface of a substrate 12;
1010—arranging a semiconductor die 14 at a die mounting region 140 of the top/front surface of the substrate 12 having raised formations 100 formed thereon;
1020—providing electrical coupling between the semiconductor die 14 and the substrate 12; and
1030—molding an electrically insulating encapsulation 20 onto the top/front surface of the substrate 12.

The flow diagram illustrated in FIG. 5B refers to embodiments of the present description where raised formations 100 (block 1000) are formed subsequently to arranging (block 1010) a semiconductor die 14 at the top/front surface of a substrate 12. In other words, add-on material may be dispensed onto a second region of the surface of the substrate 12 with the semiconductor die 14 (already) arranged at the first region 140 (or die mounting region) of the surface of the substrate 12.

The flow diagram illustrate in FIG. 5C refers to embodiments of the present description where raised formations 100 (block 1000) are formed subsequently to arranging (block 1010) a semiconductor die 14 at the top/front surface of a substrate 12 and subsequently to providing electrical coupling (block 1020) to the semiconductor die 14.

In other words, add-on material may be dispensed to provide a sculptured pattern of raised formations 100 at the top/front surface of a substrate 12 having a semiconductor die 14 provided with electrically conductive formations 16 towards the die 14. The electrically conductive formations 16 may extend along non-interfering paths with the sculptured pattern of raised formations 100.

Without prejudice to the underlying principles, the details and the embodiments may vary, even significantly, with respect to what has been described by way of example only without departing from the scope of the embodiments.

The claims are an integral part of the technical teaching provided in respect of the embodiments.

The extent of protection is determined by the annexed claims.

1. A method, comprising:
arranging a semiconductor die at a first region of a surface of a substrate;
dispensing add-on material onto a second region of the surface of said substrate;
wherein the add-on material dispensed onto the surface of the substrate provides a sculptured pattern of raised formations; and
molding electrically insulating material onto the surface of the substrate having the semiconductor die arranged at the first region of the surface of the substrate, wherein the electrically insulating material encapsulates the semiconductor die as well as said sculptured pattern of raised formations provided at the surface of the substrate, and wherein the sculptured pattern of raised formations counters delamination of the electrically insulating material molded onto the surface of the substrate from said surface of the substrate.

2. The method of claim 1, wherein dispensing add-on material comprises dispensing using an additive manufacturing technique.

3. The method of claim 2, wherein the additive manufacturing technique is a laser induced forward transfer (LIFT) technique.

4. The method of claim 1, wherein dispensing add-on material onto said second region of the surface of said substrate is performed after the semiconductor die is arranged at said first region of the surface of the substrate.

5. The method of claim 1, wherein dispensing add-on material onto said second region of the surface of said substrate is performed before the semiconductor die is arranged at said first region of the surface of the substrate.

6. The method of claim 1, further comprising electrically connected the semiconductor die to the substrate using wires, and wherein dispensing add-on material onto said second region of the surface of said substrate is performed after the semiconductor die is arranged at said first region of the surface of the substrate and the semiconductor die is electrically connected to the substrate.

7. The method of claim 1, further comprising providing in said substrate a die pad including said first region of the surface of a substrate and an array of electrically conductive leads arranged around the die pad, wherein dispensing said add-on material onto the second region of the surface of said substrate comprises dispensing add-on material at the die pad.

8. The method of claim 1, further comprising providing in said substrate a die pad including said first region of the surface of a substrate and an array of electrically conductive leads arranged around the die pad, wherein dispensing said add-on material onto the second region of the surface of said substrate comprises dispensing add-on material at the array of electrically conductive leads.

9. The method of claim 1, further comprising providing in said substrate a die pad including said first region of the surface of a substrate and an array of electrically conductive leads arranged around the die pad, wherein dispensing said add-on material onto the second region of the surface of said substrate comprises dispensing add-on material at both the die pad and at the array of electrically conductive leads.

10. The method of claim 1, comprising providing in said substrate a die pad including a central portion providing said first region of the surface of a substrate, as well as a peripheral portion around the central portion, wherein dispensing said add-on material onto said second region of the surface of said substrate comprises dispensing add-on material at said peripheral portion of the die pad.

11. The method of claim 10, comprising providing in said substrate an array of electrically conductive leads arranged around the die pad, wherein dispensing said add-on material onto the second region of the surface of said substrate comprises dispensing add-on material both at the peripheral portion of the die pad and at the array of electrically conductive leads.

12. The method of claim 1, further including providing electrically conductive formations towards the semiconductor die arranged at the first region of the surface of a substrate, wherein said electrically conductive formations extend along non-interfering paths with the sculptured pattern of raised formations.

13. The method of claim 1, wherein said raised formations comprise pillar-like formations.

14. The method of claim 1, wherein said raised formations comprise dike-like formations.

15. A device, comprising:
a semiconductor die arranged at a first region of a surface of a substrate;
add-on material at a second region of the surface of said substrate, wherein the add-on material provides a sculptured pattern of raised formations; and
electrically insulating material on the surface of the substrate, wherein the electrically insulating material encapsulates the semiconductor die as well as said sculptured pattern of raised formations provided at the surface of the substrate, and wherein the sculptured pattern of raised formations counters delamination of the electrically insulating encapsulation molded onto the surface of the substrate from said surface of the substrate.

16. The device of claim 15, wherein:
said substrate comprises a die pad including said first region of the surface of a substrate and an array of electrically conductive leads arranged around the die pad, and add-on material at the second region of the surface of said substrate comprises add-on material located at one or more of the die pad and the array of electrically conductive leads.

17. The device of claim 15, wherein:
said substrate comprises a die pad including said first region of the surface of a substrate and an array of electrically conductive leads arranged around the die pad, and add-on material at the second region of the surface of said substrate comprises add-on material located at both at the die pad and at the array of electrically conductive leads.

18. The device of claim 15, wherein:
said substrate comprises a die pad including said first region of the surface of a substrate and an array of electrically conductive leads arranged around the die pad, and add-on material at the second region of the surface of said substrate comprises add-on material located at said peripheral portion of the die pad.

19. The device of claim 15, wherein:
said substrate comprises a die pad including said first region of the surface of a substrate and an array of electrically conductive leads arranged around the die pad, and add-on material at the second region of the surface of said substrate comprises add-on material located at both at the peripheral portion of the die pad and at the array of electrically conductive leads.

20. The device of claim 15, wherein:
said substrate comprises a die pad including said first region of the surface of a substrate and an array of electrically conductive leads arranged around the die pad; and
conductive formations towards the semiconductor die arranged at the first region of the surface of a substrate, wherein said electrically conductive formations extend along non-interfering paths with the sculptured pattern of raised formations.

21. The device of claim 15, wherein said raised formations comprise pillar-like formations.

22. The device of claim 15, wherein said raised formations comprise dike-like formations.
